(19) United States
(12) Patent Application Publication
(10) Pub. No.: US 2003/0038349 A1
(43) Pub. Date: Feb. 27, 2003

(54) Glycogen phosphorylase inhibitor

(76) Inventors: Stephane Provost, Saint Jean de Braye (FR); Sophie Girard, Orleans La Source (FR); Michel Gouiller, Olivet (FR)

Correspondence Address: Schlumberger Sema Inc, Intellectual Property Department, Suite 100, 30000 Mill Creek Avenue, Alpharetta, GA, 30022, US

(21) Appl. No.: 10/221,245

(22) PCT Filed: Mar. 7, 2001
(86) PCT No.: PCT/IB01/00389

(30) Foreign Application Priority Data
Mar. 10, 2000 (FR) 0003089

(51) Int. Cl. H01L 23/02; H01L 29/40

(52) U.S. Cl. 257/679; 257/783

(57) ABSTRACT

The present invention relates to an integrated circuit having an active face (2) with terminal pads (3) therein and an inactive face (4) opposite from the active face. Respective reinforcing sheets (5, 6) cover the faces of the integrated circuit. The invention also provides a method of reinforcing integrated circuits.

The present invention relates to a reinforced integrated circuit and to a method of reinforcing integrated circuits. The invention is usable in particular in the field of portable articles such as contact or con tactless cards like bank cards or telephone cards, access cards, or indeed articles in the field of integrated circuit labels.

An integrated circuit is commonly made from a die of silicon having an active face including terminal pads and an inactive face that is opposite from the active face. Silicon is a material that is relatively fragile and it is poor at withstanding impacts and bending stresses.

In the context of an integrated circuit being implanted in a card, the integrated circuit is generally initially stuck to a support and connected to conductor areas that are secured to the support, thereby forming a module. The integrated circuit is then encapsulated in a block of resin associated with reinforcement, thereby improving the strength of the module and protecting the connections between the integrated circuit and the conductive areas. Nevertheless, such a module is relatively expensive to make. In addition, the module configuration is poorly adapted to certain types of card (in particular thin cards) and to labels, and it is poorly adapted to certain methods of manufacturing them.

The problem of the ability of integrated circuits to withstand bending is made worse by the fact that the integrated circuits in use at present in cards are of area that is tending to increase whereas their thickness is tending to decrease.

An object of the invention is to propose means for increasing the mechanical strength of integrated circuits.

The invention achieves this object by providing an integrated circuit comprising an active face including terminal pads and an inactive face opposite from the active face, a reinforcing sheet covering each of the faces of the integrated circuit.

The reinforcing sheets give the integrated circuit good strength against bending and they protect the faces they cover of the integrated circuit against impact. Integrated circuits reinforced in this way are easy to implant in thin cards or in labels. In addition, the integrated circuit can then be placed in the thickness of the body of a card in a position that is close to the neutral fiber of the card. This limits the bending stresses to which the integrated circuit is likely to be subjected.

Advantageously, the reinforcing sheet is fixed to the corresponding face of the integrated circuit by means of a layer of adhesive, the adhesive layer preferably being of thickness that is sufficient to accommodate variations of expansion between the reinforcing sheet and the integrated circuit. This makes it possible to use a reinforcing sheet having a coefficient of expansion that is different from that of the material constituting the integrated circuit proper.

The invention also provides a method of reinforcing integrated circuits each having an active face including terminal pads and an inactive face opposite from the active face, the method comprising the steps of:

depositing a reinforcing sheet on each of the faces of the integrated circuits while the integrated circuits are associated with one another in the form of a wafer; and

individualizing the integrated circuits by cutting up the wafer.

Thus, in a single operation, several hundreds of integrated circuits can be covered in the reinforcing sheet. In addition, since the reinforcing sheet is cut up simultaneously with the wafer when the integrated circuits are individualized, each reinforcing sheet is accurately positioned on the corresponding integrated circuit. Finally, the reinforcing sheet improves the strength of the wafer before it is cut up and prevents the propagation of any cracks that might be started while the wafer is being cut up.

Other characteristics and advantages of the invention will appear on reading the following description of particular, non-limiting embodiments of the invention.

Reference is made to the accompanying drawing, in which:

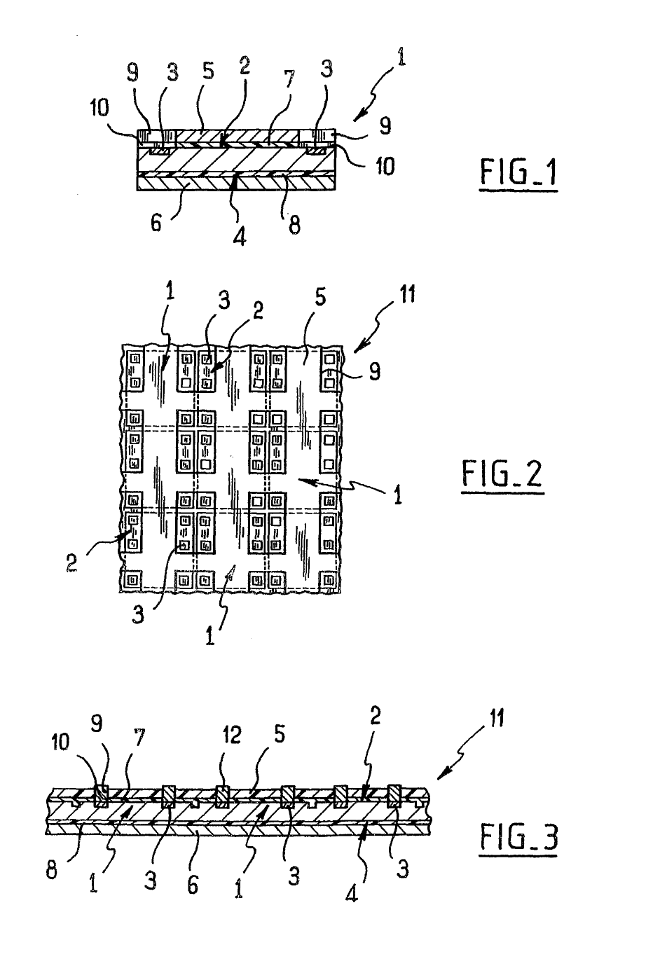

FIG. 1 is a cross-section view through an integrated circuit constituting a first embodiment of the invention;

FIG. 2 is a plan view of a wafer comprising integrated circuits of the first embodiment; and

FIG. 3 is a cross-section view of a wafer comprising integrated circuits constituting a second embodiment of the invention.

With reference to the figures, an integrated circuit 1 comprises, in conventional manner, a silicon die presenting an active face 2 with terminal pads 3 therein and an inactive face 4 that is opposite from the active face 2.

With reference more particularly to FIGS. 1 and 2, and in accordance with the invention, reinforcing sheets 5 and 6 are fixed respectively to the active face 2 and to the inactive face 4 of the integrated circuit 1 by means of respective layers of adhesive 7, 8.

In this case, the reinforcing sheets 5 and 6 are made of metal such as nickel or copper and they are about 100 micrometers (μm) thick.

The adhesive layers 7 and 8 are of thickness sufficient to compensate for variations in expansion that exists between the metal of the reinforcing sheets 5 and 6 and silicon and to accommodate the stresses generated by such variations in expansion. Thus, silicon has a coefficient of expansion of the order of 10⁻⁷ while a copper reinforcing sheet has a coefficient of expansion of about 10⁻⁶. Under such circumstances, it is possible to make the layer of adhesive 6, 8 by means of an adhesive having a coefficient of expansion of the order of 10⁻³ or 10⁻⁴ and spread to a thickness of the order of a few tens of micrometers.

The reinforcing sheet 5 and the layer of adhesive 7 covering the active face 2 present openings 9, 10 in register with the terminal pads 3.

An integrated circuit 1 is reinforced while the integrated circuit 1 is still associated with other integrated circuits in the form of a wafer given overall reference 11 and carrying several thousand integrated circuits.

The reinforcing sheets 5 and 6 are cut to wafer size and the openings 9 are made by photoetching the reinforcing sheet 5.

The active face 2 of the integrated circuits 1 is covered in a photosensitive adhesive resin to form the adhesive layer 7 and the inactive face 4 of the integrated circuits 1 is covered in an adhesive resin to form the adhesive layer 8. For each adhesive layer 7, 8 the resin can be deposited on the corresponding face 2, 4 of the wafer 11 using the spinner method which consists in setting the wafer 11 into rotation and in pouring the resin onto the corresponding face so that the resin spreads over the wafer 11 under the effect of centrifugal force.

The reinforcing sheets are then stuck in place under a primary vacuum by applying the reinforcing sheets 5 and 6 against the corresponding adhesive layers 7 and 8. Working under a primary vacuum makes it possible to ensure that no bubbles form in the adhesive layer. For the same purpose, it is also possible to make macroscopic perforations through the reinforcing sheets 5 and 6, e.g. by means of a laser, so as to allow any air that becomes imprisoned between the reinforcing sheet and the adhesive layer to escape. While the reinforcing sheet 5 is being stuck into place, the openings 9 in the reinforcing sheet 5 are placed so as to be in register with the terminal pads 3 on the wafer 11.

If the resin used is reactivatable when hot, then the adhesive layers are heated simultaneously with the reinforcing sheets 5 and 6 being applied.

The resin forming the adhesive layer 7 in register with the terminal pads 3 is then eliminated so as to form openings 10. The resin can be eliminated, for example, in conventional manner by exposing the adhesive layer 7 to ultraviolet light through the reinforcing sheet 5 which thus forms a mask, and then in etching the adhesive layer 7 by means of a solvent which acts only on those zones of the adhesive layer 7 that has been exposed, i.e. those zones which are in register with the openings 9.

In a first variant, the resin layer 7 can also be deposited on the wafer 11 of integrated circuits 1 by silk-screen printing using a screen such that the terminal pads 3 are not covered in the resin that forms the adhesive layer 7.

In a second variant, the adhesive layer 7 can be formed by a resin containing electrically conductive particles making it electrically anisotropic so that the zones of the adhesive layer 7 situated in register with the terminal pads 3 can be made locally conductive by pressing the resin while hot in a direction that is normal to the terminal pads 3.

In a third variant, the adhesive layers 7, 8 can be formed by adhesive films that are applied by hot pressing either onto the active and inactive faces 2 and 4 of the wafer 11, or else onto the reinforcing sheets 5 and 6. The reinforcing sheets 5 and 6 are then hot-pressed respectively onto the active face 2 and onto the inactive face 4 of the wafer 11.

Once the reinforcing sheets 5 and 6 have been fixed on the faces 2 and 4 of the wafer 11, the wafer is cut up in conventional manner to individualize the integrated circuits. In order to facilitate this operation, provision can be made for the reinforcing sheets 5 and 6 to have zones of reduced thickness extending along the paths that are to be followed by the cutting tool or saw.

In a variant, the method can include a step of reducing the thickness of the integrated circuit from its inactive face 4 prior to fixing the reinforcing sheet 6. By way of example, this step can be performed by polishing the inactive face 4. This makes it possible to obtain an integrated circuit which, once reinforced, is of a thickness that is similar to that of an integrated circuit that has not been reinforced.

Elements identical or analogous to those described above are given identical numerical references in the description below concerning a second embodiment of the invention.

With reference to FIG. 3, studs 12 are made on the terminal pads 3 of the integrated circuits 1 while still associated with one another in the form of a wafer 11. The studs 12 can be made by silk-screen printing. The material used for making the studs 12 is then a silver-filled polymer or a solder paste. The studs 12 can also be made by an electrochemical growth method.

The resin used for forming the adhesive layer 7 is electrically insulative and it is deposited using the spin process on the active face 2 of the integrated circuits 1 of the wafer 11. The depth of the adhesive layer 7 is less than the height of the studs 12.

The reinforcing sheet 5 has openings 9 previously formed therein to receive the studs 12 and it is then applied by being hot-pressed against the adhesive layer 7. In this case, the reinforcing sheet 5 is made of an insulating material such as a thermoplastic material. The studs 12 project slightly from the reinforcing sheet 5.

The reinforcing sheet 6 is put into place and the wafer 11 is cut up to individualize the integrated circuits 1 in the same manner as before.

Naturally, the invention is not limited to the embodiment described and variants can be applied thereto without going beyond the ambit of the invention as defined by the claims.

In particular, the reinforcing sheets 5 and 6 of the integrated circuit in FIG. 1 can be made of different metals or, more generally, of different materials. The materials used for making the reinforcing sheets 5 and 6 are preferably materials having equivalent mechanical characteristics and, for example, similar coefficients of expansion, thus making it possible to ensure that the integrated circuit or the wafer does not warp like a bimetallic strip under the effect of a rise in temperature. The reinforcing sheets 5 and 6 could also be of different thicknesses. The sum of the thicknesses of the two reinforcing sheets can thus be greater than or equal to that of a non-reinforced integrated circuit.

1/ An integrated circuit for obtaining a portable article of the smart card type, the integrated circuit having an active face (2) with terminal pads (3) therein and an inactive face (4) opposite to the active face, the integrated circuit being characterized in that a reinforcing sheet (5, 6) covers each of the faces thereof.

2/ An integrated circuit according to claim 1, characterized in that each reinforcing sheet (5, 6) is fixed to the corresponding face (2, 4) of the integrated circuit (1) by means of a layer of adhesive (7, 8).

3/ An integrated circuit according to claim 2, characterized in that each layer of adhesive (7, 8) is of a thickness that is sufficient to compensate for variations in expansion between the corresponding reinforcing sheet (5, 6) and the integrated circuit (1).

4/ An integrated circuit according to any one of claims 1 to 3, characterized in that the terminal pads (3) of the active face (2) are provided with studs (12) projecting from the reinforcing sheet (5).

5/ An integrated circuit according to any one of claims 1 to 4, characterized in that at least one of the reinforcing sheets (5, 6) is made of metal.

6/ An integrated circuit according to any preceding claim, characterized in that the reinforcing sheets (5, 6) have similar mechanical characteristics such as similar coefficients of expansion.

7/ An integrated circuit according to any preceding claim, characterized in that the reinforcing sheets (5, 6) are of substantially the same thickness.

8/ A method of reinforcing integrated circuits (1) each having an active face (2) with terminal pads (3) therein and an inactive face (4) opposite from the active face, the method being characterized in that it comprises the steps of:
depositing a reinforcing sheet (5, 6) on each of the faces of the integrated circuits while the integrated circuits are associated with one another in the form of a wafer (11); and
individualizing the integrated circuits by cutting up the wafer.

9/ A method according to claim 8, characterized in that at least one of the reinforcing sheets (5, 6) is fixed by being stuck under a primary vacuum.

10/ A method according to claim 8 or claim 9, in relation with fixing the reinforcing sheet (5) on the active face (2) of the integrated circuits, said reinforcing sheet having openings (9) for placing in register with the terminal pads (3), the method being characterized in that the reinforcing sheet is fixed on the active face by being stuck thereto by means of a layer of photosensitive adhesive (7), and in that after the reinforcing sheet has been stuck in place, the adhesive layer is exposed to radiation therethrough and the exposed zones of the adhesive layer are etched by means of a solvent.

11/ A method according to claim 8 or claim 9, in relation with fixing the reinforcing sheet (5) on the active face (2) of the integrated circuit, said reinforcing sheet having openings (9) for placing in register with the terminal pads (3), the method being characterized in that the reinforcing sheet is fixed on the active face by being stuck thereto by means of an adhesive layer (7) which is spread on the active face after studs (12) have been made on the terminal pads (3), the thickness of the adhesive layer being less than the height of the studs.

12/ A method according to any one of claims 8 to 11, characterized in that it includes the step of reducing the thickness of the integrated circuit from the inactive face (4) thereof prior to depositing the reinforcing sheet (6) on the inactive face (4).
